(19) United States
(12) Patent Application Publication
(10) Pub. No.: US 2020/0095472 A1
(43) Pub. Date: Mar. 26, 2020

(54) TRANSFER SHEET

(71) Applicant: JNC CORPORATION, Tokyo (JP)

(72) Inventors: Shin KOGA, Chiba (JP); Takeshi FUJIWARA, Chiba (JP)

(73) Assignee: JNC CORPORATION, Tokyo (JP)

(21) Appl. No.: 16/469,148

(22) PCT Filed: Nov. 27, 2017
(86) PCT No.: PCT/JP2017/042328

§ 371 Date: Jun. 13, 2019

(30) Foreign Application Priority Data
Dec. 15, 2016 (JP) 2016-243313

(51) Int. Cl. C09J 7/38; H01L 21/48; H01L 23/373; B32B 37/00; B32B 7/06; B32B 7/12; B32B 27/30; B32B 37/12; C09J 7/20

(52) U.S. Cl. CPC C09J 7/381; H01L 21/4882; H01L 23/3735; B32B 37/025; B32B 7/06; B32B 7/12; C09J 2203/326; B32B 37/1207; C09J 7/20; B32B 2457/14; C09J 2205/114; C09J 2429/00; C09J 2400/123; B32B 27/30

(57) ABSTRACT

To provide a heat radiation member having a smaller size and high performance. A transfer sheet including the following layers laminated in the following order: a release layer including a releasable film; a first adhesive layer, which includes a poly(vinyl formal) resin; a thermally conductive material layer including a carbon material; and a second adhesive layer, which includes a poly(vinyl formal) resin.

### TECHNICAL FIELD

The present invention relates to a transfer sheet and a heat radiation member using the same.

### DESCRIPTION OF RELATED ART

It is well known that heat spots are generated in electronic devices due to heat generated from electronic components included in the electronic devices such as CPUs. Measures for heat spots have become ever more important in recent years according to miniaturization of electronic devices and advanced performance of electronic components such as CPUs. A typical measure for heat spots is installing a heat radiation member. Heat radiation from a heat generating member via a heat radiation member is promoted, and thus the inside of the electronic device can have a uniform temperature. As a heat radiation member provided in a thin and small electronic device, a heat radiation sheet produced by processing a material having high thermal conductivity such as carbon materials typified by graphite into a sheet shape is used, and carbon materials such as carbon or graphite, fillers such as aluminum or silica, and the like are used as thermally conductive materials. Although graphite exhibits excellent thermal conductivity among these, it has a low adhesive property with respect to other materials such as metals and plastics and has inferior durability in response to abrasion, a pressing force, and the like, and inferior processibility in punching and cutting in comparison to other materials, and thus, graphite sheets are used as heat radiation members by superimposing them on an adhesive layer or a protective layer.

A basic form of a heat radiation sheet using graphite sheet is disclosed in Patent Literature 1. Patent Literature 1 describes a heat radiation member having a sheet formed of a graphite material and an adhesive layer having a thickness of 100 μm or thinner provided on a surface of the sheet. An acryl-based liquid glue is used for the adhesive layer, an adhesive strength between the graphite and a heating element and the thermal diffusion thereof are good when a thickness of the adhesive layer is in the range of 20 μm to 100 μm. However, it is not possible to adopt a heat radiation sheet with such an adhesive layer having a thickness over 20 μm to the fine electronic component shapes of recent years. In addition, it is expected that thermal resistance would be able to be reduced further by further thinning the thickness of the adhesive layer as long as adhesiveness strength can be secured.

Patent Literature 2 describes manufacturing of graphite having a coated resin film by coating one surface or both surfaces of a graphite sheet with a solution-state resin. While flexibility of the graphite sheet is improved and detachment of graphite powder is curbed due to the coated resin film, Patent Literature 2 makes no mention of an adhesive property between the graphite sheet and the heating element and improvement in the heat radiation effect of the graphite sheet.

Patent Literature 3 describes a thermally conductive sheet having an expanded graphite sheet, a coating layer made of a thermosetting resin formed on an upper surface of the expanded graphite sheet, and an adhesive layer formed on a lower surface of the expanded graphite sheet. Although this thermally conductive sheet has excellent heat radiation properties and little fall of graphite powder, it uses an adhesive film having a total thickness of 15 μm for the adhesive layer and has room for improvement in terms of balance between thinning of the entire heat radiation sheet and adhesive strength.

Patent Literature 4 describes an adhesive film for protecting a graphite sheet. Although a laminated sheet manufactured by attaching such an adhesive film to a graphite sheet has excellent processibility in punching and cutting, when such a laminated sheet is used as a heat radiation member, there are disadvantages that the manufacturing steps of the heat radiation member are complicated and the thickness of the entire heat radiation member increases. In addition, Patent Literature 4 does not disclose an adhesive property of the laminated sheet with respect to a heating element nor the heat radiation performance thereof.

As described above, a heat radiation sheet using a carbon material as a heat radiation material and having all of an ultra-thin shape compatible with miniaturization of electronic devices and electronic components, an excellent adherence property with respect to heating elements, and excellent processibility has not yet been obtained.

### REFERENCE LIST

### Patent Literature

### [Patent Literature 1]

Japanese Patent Application Laid-Open (JP-A) No. H11-317480

### [Patent Literature 2]

Japanese Patent Application Laid-Open (JP-A) No. 2002-12485

### [Patent Literature 3]

Japanese Patent Application Laid-Open (JP-A) No. 2007-83716

### [Patent Literature 4]

Japanese Patent Application Laid-Open (JP-A) No. 2015-71727

### SUMMARY

### Technical Problem

An objective of the present invention is to provide a heat radiation member using a carbon material as a heat radiation material and having all of an ultra-thin shape compatible with miniaturization of electronic devices and electronic components, an excellent adherence property with respective to a member including a heat source, and excellent processibility. The problem of the related art described above is that a method for causing a radiator made of a thermally conductive material such as graphite to firmly adhere to a member including a heat source without impairing the thermal conductivity and processibility of the radiator has not been found. Therefore, the inventors of the present invention searched for an adhesive agent suitable for causing a radiator made of a thermally conductive material such as graphite to adhere to a member including a heat source. As a result, the inventors studied a laminated film that has a thermally conductive material layer made of graphite or the like and an adhesive layer including poly(vinyl formal) and can promote thermal diffusion by being firmly adhered to a surface of another member with a simple operation.

### Solution to Problem

As a result, the present inventors found a laminated film in which adhesive layers including a vinyl formal resin are provided on both surfaces of a thermally conductive material layer including a carbon material such as graphite, and a release layer is provided on a surface of one of the adhesive layers. A protective layer can be arbitrarily provided on the surface of the other adhesive layer of the laminated film. Such a laminated film can be stored in a wound shape or a flat sheet shape. If the release layer is removed and the adhesive layer is made to adhere to another member, the thermally conductive material layer can be simply transferred to a surface of the other member. Even if a thickness of the single adhesive layer is 5 μm or thinner, the thermally conducive material layer firmly adheres to a metal, an electronic member, or the like via the adhesive layer and exhibits an excellent heat radiation effect. That is, the present invention is as follows.

[1] A transfer sheet in which a release layer including a releasable film, a first adhesive layer including a poly(vinyl formal) resin, a thermally conductive material layer including a carbon material, and a second adhesive layer including a poly(vinyl formal) resin are laminated in this order.

[2] The transfer sheet described in [1] above, in which the poly(vinyl formal) resin includes the following structural units A, B, and C.

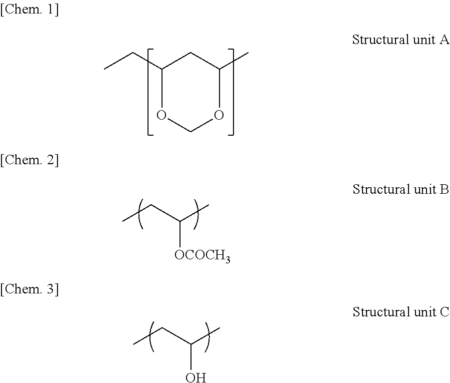

[3] The transfer sheet described in [2] above, in which the structural units A, B, and C in the poly(vinyl formal) resin are bonded at random, a content of the structural unit A is 80 to 82 weight %, a content of the structural unit B is 9 to 13 weight %, and a content of the structural unit C is 5 to 7 weight % with respect to the total amount of the structural units A, B, and C.

[4] The transfer sheet described in [3] above, in which a weight-average molecular weight of the poly(vinyl formal) resin is in the range of 30,000 to 150,000.

[5] The transfer sheet described in any one of [1] to [4] above, in which the thermally conductive material layer is made of a carbon material selected from graphite, graphene, and carbon nanotubes.

[6] The transfer sheet described in any one of [1] to [5] above, in which a thickness of each of the first and second adhesive layers is in a range of 1 to 20 μm.

[7] A manufacturing method for the transfer sheet described in any one of [1] to [6] above in which the following steps 1, 2, and 3, are performed in this order.

(Step 1) A step of forming the first adhesive layer including a poly(vinyl formal) resin on an open surface of the thermally conductive material layer made of the carbon material formed on a carrier film.

(Step 2) A step of forming the release layer including the releasable film on an open surface of the first adhesive layer and removing the carrier film from the thermally conductive material layer.

(Step 3) a step of forming the second adhesive layer including a poly(vinyl formal) resin on the open surface of the thermally conductive material layer.

[8] The manufacturing method for the transfer sheet described in [7] above, in which the following step 4 is further performed after step 3.

(Step 4) A step of forming a protective layer on an open surface of the second adhesive layer.

[9] A formation method for a heat radiation member using the transfer sheet described in any one of [1] to [6] above, in which the following steps 5, 6, and 7 are performed in this order.

(Step 5) A step of thermally compression-bonding an outermost surface of the second adhesive layer forming the transfer sheet to an item.

(Step 6) A step of removing the release layer forming the transfer sheet.

(Step 7) A step of thermally compression-bonding an outermost surface of the first adhesive layer forming the transfer sheet to the item.

[10] The formation method for the heat radiation member described in [9], in which at least one of the items has an electronic component as a heat source.

### Advantageous Effects of Invention

If the transfer sheet of the present invention is used, the thermally conductive material layer can be transferred to a heat source with a simple operation. The transferred thermally conductive material layer firmly adheres to the heat source via an extremely thin adhesive layer and exhibits an excellent heat radiation property. As a result, an extremely thin heat radiation sheet having excellent heat radiation performance can be made to firmly adhere to the heat source through a simple operation.

### BRIEF DESCRIPTION OF THE DRAWINGS

FIG. 1 is a schematic cross-sectional diagram of a first example of a transfer sheet of the present invention.

FIG. 2 is a schematic cross-sectional diagram of a second example of the transfer sheet of the present invention.

FIG. 3 is a schematic diagram illustrating step 1 of a manufacturing method for the transfer sheet of the present invention.

FIG. 4 is a schematic diagram illustrating step 2 of the manufacturing method for the transfer sheet of the present invention.

FIG. 5 is a schematic diagram illustrating step 3 of the manufacturing method for the transfer sheet of the present invention.

FIG. 6 is a schematic diagram illustrating step 4 that may be included in the manufacturing method for the transfer sheet of the present invention.

FIG. 7 is a schematic diagram illustrating step 5 of a formation method for a heat radiation member using the transfer sheet of the present invention.

FIG. 8 is a schematic diagram illustrating step 6 of the formation method for the heat radiation member using the transfer sheet of the present invention.

FIG. 9 is a schematic diagram illustrating step 7 of the formation method for the heat radiation member using the transfer sheet of the present invention.

FIG. 10 is a schematic diagram illustrating an example of a heat radiation member formed using the transfer sheet of the present invention.

FIG. 11 is a schematic diagram illustrating an example of a heat radiation member formed using a method of the related art.

FIG. 12 is a schematic diagram illustrating an example of a heat radiation member formed using a method of the related art.

### DESCRIPTION OF THE EMBODIMENTS

[Transfer Sheet]

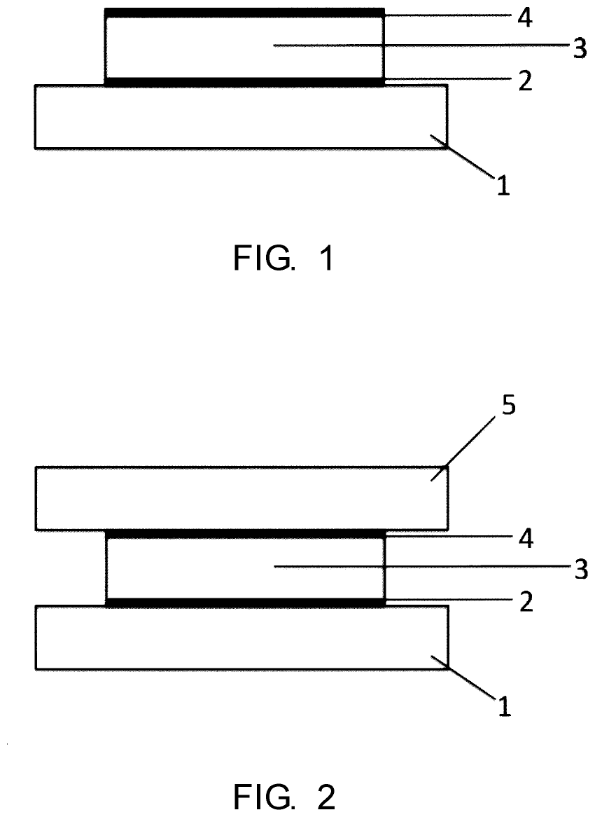

A transfer sheet of the present invention is a member for transferring a layer made of a thermally conductive material to another member having a heat generation part and has a form of a laminated body. It has a structure in which the transfer sheet of the present invention, a release layer including a releasable film, a first adhesive layer, which includes a poly(vinyl formal) resin, a thermally conductive material layer including a carbon material, and a second adhesive layer, which includes a poly(vinyl formal) resin are laminated in this order (e.g., the structure illustrated in FIG. 1). The transfer sheet of the present invention may further include a protective layer (e.g., as illustrated in FIG. 2).

The transfer sheet of the present invention employs a structure in which the thermally conductive material layer is interposed between the two adhesive layers which include extremely thin poly(vinyl formal) resins. The thermally conductive material layer can be simply transferred to a surface of another member via the adhesive layer by removing the release layer and/or protective film from the transfer sheet of the present invention and compression-bonding the exposed adhesive layer to the other member. Although the adhesive layer is very thin, the thermally conductive material layer is firmed fixed to the surface of the other member via the adhesive layer. In a case in which the other member has a heat generation part, heat from the other member is conducted to the adhesive layer and the thermally conductive material layer. The thermally conductive layer transferred as described above constitutes a heat radiation member with the adhesive layers.

[Thermally Conductive Material]

The thermally conductive material layer included in the transfer sheet of the present invention is made of a carbon material. Any material that can be processed to be a thin layer can be used as the carbon material without restriction. Graphite, graphene, carbon nanotubes, and the like can be used as the carbon material. Among these, graphite is preferred due to its price and processibility. As graphite, graphite sheets that are marketed products can be used without restriction. In addition, graphite manufactured using the method described in Japanese Patent Application Laid-Open (JP-A) No. S61-275117 or Japanese Patent Application Laid-Open (JP-A) No. H11-21117 can be used in the present invention as well.

Examples of marketed products thereof include eGRAF SPREADERSHIELD SS series (manufactured by GrafTECH International), Graphinity (manufactured by Kaneka Corporation), PGS graphite sheets (manufactured by Panasonic Corporation), and the like as artificial graphite sheets manufactured from synthetic resin sheets, and include eGRAF SPREADERSHIELD SS-500 (manufactured by GrafTECH International) and the like as natural graphite sheets manufactured from natural graphite.

A thickness of the thermally conductive material layer formed of such graphite is not particularly limited. Although it is preferable for the thermally conductive material layer to be a thick layer to obtain a heat radiation member having an excellent heat radiation property, a thickness of the thermally conductive material layer is preferably 15 to 600 μm, more preferably 15 to 500 μm, and particularly preferably 20 to 300 μm, in terms of balance between the adhesive property and heat radiation effect of the transferred thermally conductive material layer.

[Poly(Vinyl Formal) Resin]

The first and second adhesive layers included in the transfer sheet of the present invention are made of a poly(vinyl formal) resin. Poly(vinyl formal) resins are also known by the collective name of “Vinylon.” Poly(vinyl formal) resins are resins acetalized by causing formaldehyde to react with polyvinyl alcohol in the presence of an acidic catalyst. In this reaction, formalization further occurs at 1,3-diol parts of the polyvinyl alcohol, a ring-shaped 1,3-dioxane structure is generated, and a small amount of hydroxyl groups remain unreacted.

The poly(vinyl formal) resin used in the adhesive layers of the present invention preferably includes the following structural units A, B, and C.

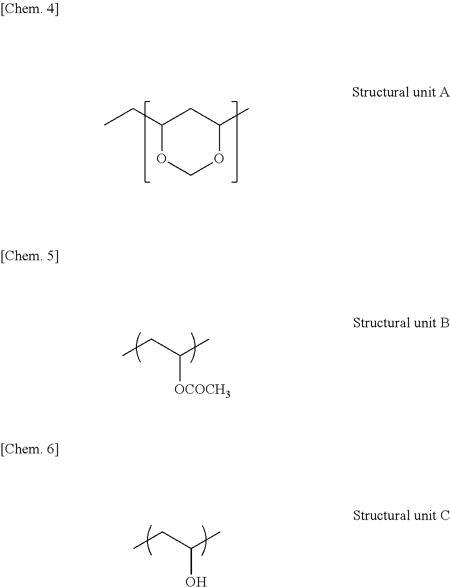

The total amount of the structural units A, B, and C is preferably 80 to 100 mass % with respect to all structural units of the poly(vinyl formal) resin. The poly(vinyl formal) resin preferably used in the present invention has the structural units A, B, and C bonded at random, including the structural unit A at a proportion of 80 to 82 mass %, the structural unit B at a proportion of 9 to 13 mass %, and the structural unit C at a proportion of 5 to 7 mass % with respect to the total amount of the structural units A, B, and C. In addition, a weight-average molecular weight of the poly(vinyl formal) resin preferably used in the present invention is in the range of 30,000 to 150,000 and preferably in the range of 40,000 to 60,000.

The poly(vinyl formal) resin including the structural units A, B, and C at the specific proportions and moreover having this specific molecular weight has better mechanical characteristics regarding tensile strength, bending strength, impact resistance, and the like than those of other resins named Vinylon, for example, a resin named a vinyl butyral resin. In addition, the poly(vinyl formal) resin has a high glass transition temperature and softening point, and can maintain adhesiveness even when it is used for semiconductor elements which have come to have an increasing operation temperature recently. If such a poly(vinyl formal) resin is used in adhesives, it can firmly adhere to items in very small doses, and the parts adhering to the items exhibit high strength, durability, and stability. By using a poly(vinyl formal) resin particularly in the adhesive layers in the transfer sheet of the present invention, the thermally conductive material layer can be held via the extremely thin adhesive layers, the thermally conductive material layer can be transferred to a surface of another member with a simple operation with high accuracy, and the thermally conductive material layer can firmly adhere to the member.

In the present invention, “Vinylec” (registered trademark) manufacture by JNC Corporation can be used as the poly(vinyl formal) resin.

A thickness of each of the first and second adhesive layers of the transfer sheet of the present invention is in the range of 1 to 20 μm, or preferably in the range of 1 to 10 μm. Although a thickness of the adhesive layers may be set to a minimum thickness in which both a surface roughness of an adhesion target and a surface roughness of a carbon material can be filled, it is preferable if the thickness can minimize thermal resistance of the laminated body including the transfer sheet and the thermally conductive material layer thereof. By designing the adhesive layers to be such extremely thin layers, a pressed ultra-thin heat radiation part is formed in an item to which the transfer sheet of the present invention is applied without performing punching, intensive compression, or the like thereon, and a good balance between the strong adhesion of the thermally conductive material layer to the surface of the item and the heat radiation effect from the item can be attained in the heat radiation part.

[Thermally Conductive Filler]

In the present invention, a thermally conductive filler may be blended into the first and/or second adhesive layer. Although there is no limit on the thermally conductive filler, a metal such as metal powder, metal oxide powder, metal nitride powder, metal hydroxide powder, metal oxynitride powder, and metal carbide powder, or a metal compound-containing filler, a filler containing a carbon material, and the like may be used.

Examples of the metal powder include powder of a metal such as gold, silver, copper, aluminum, and nickel, an alloy containing such a metal, and the like. Examples of the metal oxide powder include aluminum oxide powder, zinc oxide powder, magnesium oxide powder, silicon oxide powder, silicate powder, and the like. Examples of the metal nitride powder include aluminum nitride powder, boron nitride powder, silicon nitride powder, and the like. Examples of the metal hydroxide powder include aluminum hydroxide powder, magnesium hydroxide powder, and the like. Examples of the metal oxynitride include aluminum oxynitride powder, and the like, and examples of the metal carbide powder include silicon carbide powder, tungsten carbide powder, and the like.

Among these, aluminum nitride powder, aluminum oxide powder, zinc oxide powder, magnesium oxide powder, silicon carbide powder, and tungsten carbide powder are preferred in terms of thermal conductivity, availability, and the like.

Further, when the thermally conductive material layer is transferred onto a surface of a metal using the transfer sheet of the present invention, it is preferable to use a filler containing the same kind of metal as the metal to which the thermally conductive material layer is transferred as a prior thermally conductive filler. When the metal to which the thermally conductive material layer is transferred is of a different kind from the metal forming the prior thermally conductive filler, local cells are formed between the metal to which the thermally conductive material layer is transferred and the prior thermally conductive filler, and thus the metal layer or the filler may corrode.

Although a form of the metal or the metal compound-containing filler is not particularly limited, examples thereof include particulate (including spherical and ellipsoidal shapes), a flat shape, a columnar shape, a needle shape (including tetrapod and branch shapes), an undefined shape, and the like. These shapes can be viewed using a laser diffraction/scattering particle size distribution measuring device or a scanning electron microscope (SEM).

As the metal or metal compound-containing filler, aluminum nitride powder, aluminum oxide powder, and needle-shaped (particularly, tetrapod-shaped) zinc oxide powder are preferably used. Although zinc oxide has lower thermal conductivity than aluminum nitride, when tetrapod-shaped zinc oxide powder is used, a heat radiation member having better heat radiation characteristics is obtained than when particulate zinc oxide powder is used. In addition, when tetrapod-shaped zinc oxide powder is used as the metal or metal compound-containing filler, the likelihood of inter-layer release between the metal layer and the graphite layer can be reduced due to the anchoring effect caused by the needle-shaped parts that thrust into the carbon material. In addition, although aluminum oxide has lower thermal conductivity than aluminum nitride and zinc oxide, it is chemically stable and neither reacts with water or acid nor dissolves in water or acid, and thus a heat radiation member having high weather resistance can be obtained. When aluminum nitride powder is used as the metal or metal compound-containing filler, a heat radiation member having better heat radiation characteristics can be obtained.

An average diameter of the thermally conductive filler is 0.001 to 30 μm, and typically 0.01 to 20 μm. When the thermally conductive filler has the form of tubes or fibers, the average diameter indicates an average length of the tubes or fibers used as the thermally conductive filler. The average diameter is appropriately selected according to a target size of the heat radiation member, thicknesses of the adhesive layers, and the like. In terms of the thermal conductivity of the adhesive layers of the laminated body in the superimposing direction or the like, the average diameter is set to be smaller than the thickness of the adhesive layers. Further, the average diameter of the metal or metal compound-containing filler can be viewed using a laser diffraction/scattering particle size distribution measuring device or a scanning electron microscope (SEM).

Examples of the filler made of a carbon material include graphite powder (natural graphite, artificial graphite, expanded graphite, or Ketjenblack), carbon nanotubes, diamond powder, carbon fibers, fullerenes, and the like, and among these, graphite powder, carbon nanotubes, and diamond powder are preferred in terms of good thermal conductivity and the like.

As the thermally conductive filler, a marketed product having an average diameter and a form in a desired range may be used as it is, or a filler produced by grinding, classifying, and heating a marketed product having an average diameter and a form in the desired range may be used.

Further, since an average diameter and a form of the thermally conductive filler may be changed in the manufacturing process of the heat radiation member of the present invention, a filler having the average diameter and form may be blended with the composition.

As the thermally conductive filler, a marketed product that has undergone a surface treatment such as a dispersion treatment or a waterproofing treatment may be used as it is, or a filler produced by removing a surface treatment agent from a marketed product may be used. In addition, a marketed product that has not undergone surface treatment may be used after performing a surface treatment thereon. Particularly, since aluminum nitride and magnesium oxide are easily degraded due to moisture included in the air, a waterproofing filler is desirably used. As a thermally conductive filler, the above-described fillers may be used alone or two or more kinds thereof may be used together.

An amount of the thermally conductive filler blended in is preferably 1 to 80 volume %, more preferably 2 to 40 volume %, and even more preferably 2 to 30 volume % with respect to 100 volume % of the adhesive layers. If the thermally conductive filler is included in the adhesive layers in that amount, this is preferable for improving the thermal conductivity of the adhesive layers while maintaining adhesiveness. If an amount of the thermally conductive filler blended in is the upper limit of the range or smaller, a preferable adhesive layer having higher adhesive strength with respect to the metal layer and graphite layer is obtained, and if an amount of the thermally conductive filler blended in is the lower limit of the range or greater, a preferable adhesive layer having high thermal conductivity is obtained.

Since the strength of the adhesive layers is improved due to blending in of the thermally conductive filler, even if the thickness of the first adhesive layer and/or the second adhesive layer is further thinned, adhesiveness of the thermally conductive material layer and folding characteristics and processibility of the transfer sheet can be maintained. Besides, since the thermal conductivity of the adhesive layers is improved due to the thermally conductive filler, the heat radiation effect from the thermally conductive material layer and the adhesive layers is improved as well. The transfer sheet of the present invention having the first and/or second adhesive layer in which a thermally conductive filler has been blended is particularly useful for forming a heat radiation sheet of a light-weight and miniaturized electronic device, and a battery that is designed to cause few problems resulting from heat generation even when having a high energy density.

[Additives]

In the transfer sheet of the present invention, conventional additives such as an antioxidant, a silane coupling agent, a thermosetting resin such as an epoxy resin, a hardening agent, a crosslinking agent, a copper inhibitor, a metal deactivator, a rust inhibitor, tackifier, an anti-aging agent, a defoamer, an antistatic agent, or a weather resistance agent may be blended into the first and/second adhesive layer.

When a resin forming the adhesive layers is degraded due to contact with a metal, for example, addition of a copper inhibitor or a metal deactivator thereto as exemplified in Japanese Patent Application Laid-Open (JP-A) No. H5-48265 is preferable, addition of a silane coupling agent is preferable to improve adhesiveness of the thermally conductive filler to a polyvinyl acetal resin, and addition of an epoxy resin to is preferable to improve heat resistance (glass transition temperature) of the adhesive layers.

As the silane coupling agent, silane coupling agents (product names are 5330, S510, S520, and S530) manufactured by JNC Corporation and the like are preferable.

An addition amount of the silane coupling agent is preferably 1 to 10 parts by weight with respect to a total amount of 100 parts by weight of the resin included in the adhesive layers in terms of improvement in adhesiveness of the adhesive layers to the metal layer or the like.

Further, when heat resistance is required, addition of a crosslinking agent having multiple oxazoline groups or oxetane groups is preferable. Among these, a compound having an oxazoline group tends to be unlikely to generate a by-product such as water when it reacts with a polyvinyl acetal resin, and when this compound is used by adding the agent to the adhesive layers of the present invention, adhesive layers that are unlikely to have reduced adhesiveness even at a high temperature and have good heat resistance can be obtained.

As such a crosslinking agent having an oxazoline group, for example, EPOCROS K series, EPOCROS WS series, and EPOCROS RPS manufactured by Nippon Shokubai Co., Ltd. are available. In the present invention, for example, EPOCROS WS-500, EPOCROS RPS-1005 among the products can be used. In addition, 2,2′-(1,3-phenylene)bis(2-oxazoline) manufactured by Mikuni Pharmaceutical Industrial Co., Ltd. which is a marketed product which is a low-molecular-weight compound having an oxazoline group can also be used.

When such a crosslinking agent is added to the first and/second adhesive layer of the transfer sheet of the present invention, it is preferable for the poly(vinyl formal) resin forming the adhesive layers to include the above-described structural units A, B, and C and to further include the following structural unit D (in which a group R1 included in the following structural unit D is an alkyl group having 1 to 5 carbon atoms or a hydrogen atom).

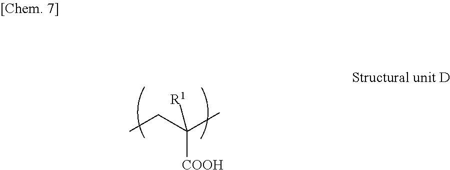

In a case in which the poly(vinyl formal) resin forming the adhesive layers of the present invention includes the structural unit D, the structural unit D is generally included at a proportion of 0.1 to 50 weight % or preferably at a proportion of 1 to 30 weight % with respect to the total amount of the structural units A, B, and C. When the poly(vinyl formal) resin includes the structural unit D in such a proportion, the cross-linked part can be increased and the mechanical strength and heat resistance can be improved.

However, the poly(vinyl formal) resin forming the adhesive layers of the present invention is a resin that has been used in enamel wires and the like in the past, hardly is degraded due to contact with a metal and degrades metals. However, in order to further maintain stability and durability, a copper inhibitor or a metal deactivator may be added to the adhesive layers when a heat radiation member having the transfer sheet of the present invention is used in an environment with a high temperature and humidity or the like. As such a copper inhibitor, Mark ZS-27 and Mark CDA-16 manufactured by ADEKA Corporation; SANKO-EPOCLEAN manufactured by Sanco Chemical Industry Co., Ltd.; Irganox MD 1024 manufactured by BASF SE, and the like are preferred. An amount of the copper inhibitor added is preferably 0.1 to 3 parts by weight with respect to the total amount of 100 parts by weight of the resin included in the adhesive layers in terms of preventing the part of the resin of the adhesive layers in contact with a metal from being degraded or the like.

[Release Layer]

As a release layer formed in the transfer sheet of the present invention, a releasable film is used without restriction. As such a releasable film, a plastic film such as a polyethylene terephthalate, polypropylene, or polyester film, paper, a foam sheet, metal foil, a laminated body formed of layers selected from these materials, or the like can be used. A plastic film such as a polyethylene terephthalate film is preferred as such a releasable film due to excellent surface smoothness. A mold release agent can also be coated onto a surface of the releasable film. As a mold release agent, a known conventional mold release agent such as a silicone-based, fluorine-based, long-chain alkyl-based, or aliphatic amide-based mold release agent can be used without restriction.

An antistatic treatment may be performed on the release layer. There is no restriction on a method of the antistatic treatment, and for example, any known method such as coating an antistatic agent on the release layer, kneading it with the releasable film material, or depositing it on the release layer, or the like may be used.

A thickness of the release layer of the present invention is generally 20 to 100 μm, and preferably 30 to 75 μm.

[Protective Layer]

A protective layer can be further provided on the second adhesive layer of the transfer sheet of the present invention. Due to this protective layer, oxidation resistance of the second adhesive layer of the transfer sheet of the present invention can be improved and scratches or damage that may degrade adhesiveness can be prevented. A resin film is preferable as the protective layer to be used in the present invention. As such a resin film, a film made of a heat resistant resin such as polypropylene or polyester is suitable, and among these, a stretched film of self-adhesive polypropylene or a masking film produced by superimposing a self-adhesive layer on a base material made of polyethylene terephthalate is preferred.

The protective layer can be placed on the transfer sheet of the present invention so as to be released from the second adhesive layer. In this case, a protective film obtained by coating a coating material on the releasable film forming the above-described release layer can be used as the protective layer. In this case, at the time of use of the transfer sheet of the present invention, the portion thereof from which both the release layer and the protective layer have been removed is made to adhere to another item, and as a result, the thermally conductive material layer is transferred to the other item.

[Manufacturing Method of Transfer Sheet]

The transfer sheet of the present invention can be manufactured by performing the following steps 1, 2, and 3 in this order.

(Step 1) The step of forming the first adhesive layer including a poly(vinyl formal) resin on an open surface of the thermally conductive material layer made of the carbon material formed on a carrier film.

(Step 2) The step of forming the release layer including a releasable film on an open surface of the first adhesive layer and removing the carrier film from the thermally conductive material layer.

(Step 3) The step of forming the second adhesive layer including a poly(vinyl formal) resin on the open surface of the thermally conductive material layer.

In the manufacturing of the transfer sheet of the present invention, the following step 4 can also be performed after step 3.

(Step 4) The step of forming the protective layer on an open surface of the second adhesive layer.

Steps 1, 2, 3, and 4 will be described below.

### [Step 1]

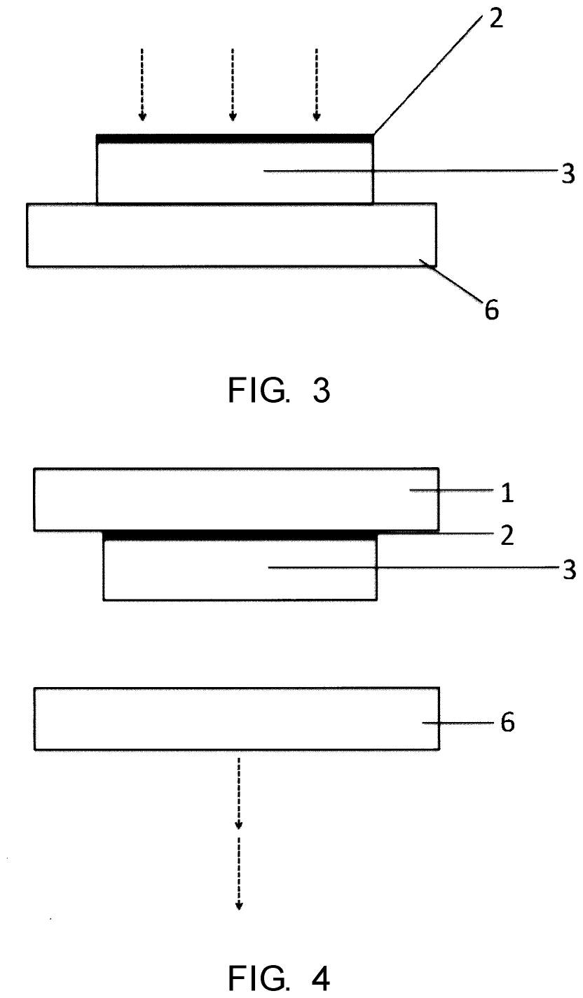

An overview of step 1 is illustrated in FIG. 3. In step 1, first, the thermally conductive material layer is laminated onto the carrier film. Any film can be used as the carrier film used here without restriction as long as it is a film to which the thermally conductive material layer stably adheres while the first adhesive layer is formed on the thermally conductive material layer. A material of the carrier film may be the same as that of the material of the above-described releasable film forming the release layer composing the transfer sheet of the present invention. However, the carrier film used in step 1 is removed before the completion of the transfer sheet of the present invention, that is, in step 2 which will be described below.

In step 1 of the present invention, then, a solution including the poly(vinyl formal) resin is coated on the open surface of the thermally conductive material layer, the solution surface is heated and dried, and thereby the first adhesive layer including the poly(vinyl formal) resin is formed. The solution can be blended with the above-described thermally conductive filler and/or an additive.

There is no particular restriction on the solution for diluting the poly(vinyl formal) resin, and for example, an alcohol-based solvent such as methanol, ethanol, n-propanol, iso-propanol, n-butanol, sec-butanol, n-octanol, diacetone alcohol, and benzyl alcohol; a cellosolve-based solvent such as methyl cellosolve, ethyl cellosolve, and butyl cellosolve; a ketone-based solvent such as acetone, methyl ethyl ketone, cyclohexanone, cyclopentanone, and isophorone; an amide-based solvent such as N,N-dimethylacetamide, N,N-dimethylformamide, and 1-methyl-2-pyrrolidone; an ester-based solvent such as methyl acetate, and ethyl acetate; an ether-based solvent such as dioxane, and tetrahydrofuran; a chlorinated hydrocarbon-based solvent such as dichloromethane, methylene chloride, and chloroform; an aromatic solvent such as toluene, and pyridine; dimethyl sulfoxide; acetic acid; terpineol; butyl carbitol; butyl carbitol acetate, and the like, and a mixed solvent having two or more kinds selected from the above solvents may be used.

Although a method for the coating is not particularly limited, a wet coating method in which the poly(vinyl formal) resin solution can be uniformly coated is preferable. Among wet coating methods, a spin coating method in which a simple and homogeneous film can be formed is preferable when a thin adhesive layer is formed. In a case in which productivity is focused on, a gravure coating method, a die coating method, a bar coating method, a reverse coating method, a roll coating method, a slit coating method, a spray coating method, a kiss coating method, a reverse kiss coating method, an air knife coating method, a curtain coating method, a lot coating method, and the like are preferable. An applicator, a doctor blade, or the like can also be used to perform coating in a uniform thickness. An amount of the coated poly(vinyl formal) resin solution is adjusted such that a final thickness of the first adhesive layer is in the range of 1 to 20 μm, and preferably in the range of 2 to 10 μm.

After the coating, the coated surface is dried. There is no restriction on the drying means. It may be placed still and dried at room temperature for about one to seven days, or may be heated and dried at a temperature that is higher than the boiling point of the solvent and lower than the softening point of the poly(vinyl formal) resin. The heating and drying may be performed in the air or an inert gas atmosphere such as nitrogen or a rare gas, or may be performed under any of atmospheric pressure, reduced pressure, and reduced pressure. When the drying is finished, the first adhesive layer is formed on the thermally conductive material layer.

[Step 2] An overview of step 2 is illustrated in FIG. 4. In step 2 of the present invention, the release layer is formed by adhering the releasable film onto the open surface of the first adhesive layer formed in step 1, and the carrier film is removed from the thermally conductive material layer. A known means can be used as a method of attaching the releasable film to the surface of the first adhesive layer formed in step 1 without restriction. By removing the single film in step 2, a sheet in which the release layer, the first adhesive layer, and the thermally conductive material layer have been laminated in this order is obtained.

[Step 3]

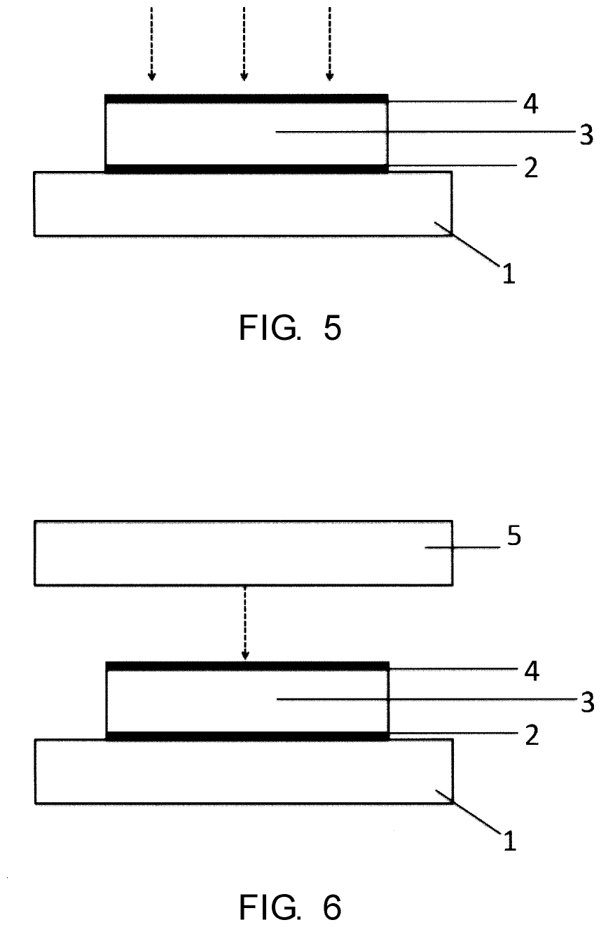

An overview of step 3 is illustrated in FIG. 5. In step 3 of the present invention, the second adhesive layer is further formed on the sheet obtained in step 2 in which the release layer, the first adhesive layer, and the thermally conductive material layer have been laminated in this order. That is, the second adhesive layer including the poly(vinyl formal) resin is formed on the open surface of the thermally conductive material layer in step 3 in the same method as the above-described formation method of the first adhesive layer. In this way, the transfer sheet of the present invention is completed.

[Step 4]

An overview of step 4 is illustrated in FIG. 6. Step 4 of the present invention is a step performed arbitrarily after step 3. In step 4, the above-described protective layer is made to adhere onto the outer surface of the second adhesive layer formed in step 3. In this way, the protective layer that permanently adheres to or can be released from the surface of the second adhesive layer is formed. In this way, the transfer sheet of the present invention having the protective layer is completed.

The transfer sheet of the present invention may have a form of being wound so that the release layer is located outside without the protective layer, or may have a form of a flat sheet having the protective layer and having the release layer and the protective layer as an outermost layer.

[Transfer of Thermally Conductive Back Material Layer]

The transfer sheet of the present invention has a good balance between tensile strength, bending strength, a stretch, elasticity, and impact resistance, and is used by being cut into various shapes according to the size and shape of an item to which the thermally conductive material layer is to be transferred. When the transfer sheet of the present invention is used, the thermally conductive material layer can be firmly fixed between items of two types via the extremely thin first and second adhesive layers without punching or high pressure treatment. In a case in which at least one of the items has a heat generation part, the fixed thermally conductive material layer functions as a heat radiator. Thus, a heat radiation member can be formed by transferring the thermally conductive material layer using the transfer sheet of the present invention.

A formation method of the heat radiation member using the above-described transfer sheet is a method of typically performing the following steps 5, 6, and 7 in this order.

(Step 5) The step of thermally compression-bonding the outermost surface of the second adhesive layer forming the transfer sheet to an item.

(Step 6) The step of removing the release layer forming the transfer sheet.

(Step 7) The step of thermally compression-bonding the outermost surface of the first adhesive layer forming the transfer sheet to the item.

Steps 5, 6, and 7 will be described below.

[Step 5]

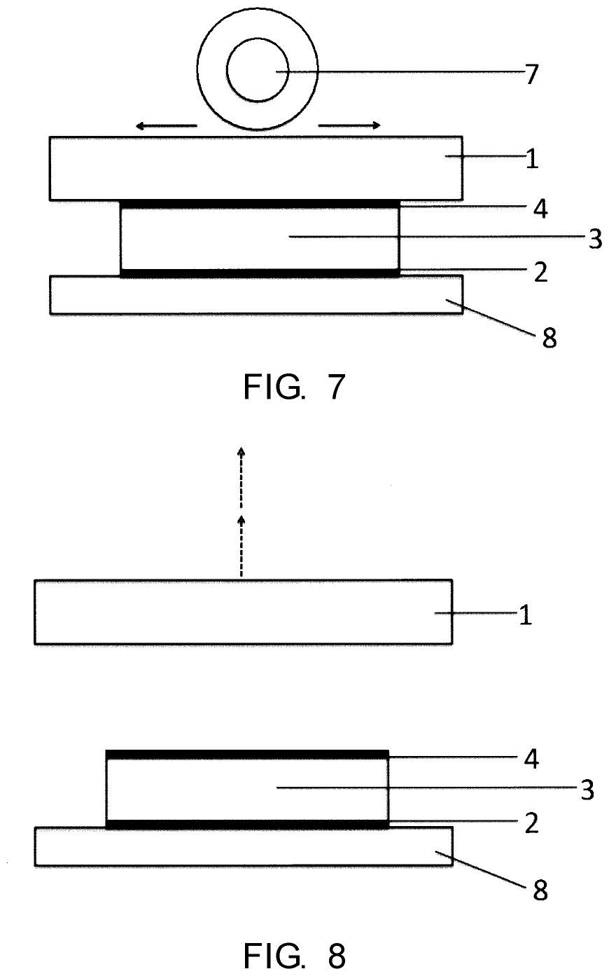

An overview of step 5 is illustrated in FIG. 7. An example in which a graphite sheet is inserted into and fixed to two aluminum plates using a transfer sheet will be described below. In a case in which the graphite sheet is another thermally conductive material layer and the aluminum plates are other items, the same operation as this example is performed. As illustrated in FIG. 7, the aluminum plates are made to adhere to the open surfaces of the second adhesive layer forming the transfer sheet of the present invention, it is heated while receiving a moderate pressing force from the outer surface of the release layer, and thereby the second adhesive layer adheres to the aluminum plates. FIG. 7 illustrates the state in which the sheet is pressed by a roller (7). The arrows present on the lower side of the roller (7) indicate reciprocating motions of the roller (7). A pressurized temperature is a temperature higher than the softening point of the poly(vinyl formal) resin at which thermal degradation of the material forming the pressed transfer sheet is a minimum, and is generally 150 to 200° C., and preferably 155 to 180° C.

[Step 6]

An overview of step 6 is illustrated in FIG. 8. In step 6, the release layer forming the transfer sheet of the present invention is removed from the first adhesive layer. As a result, one side of the first adhesive layer forming the transfer sheet of the present invention is open.

[Step 7]

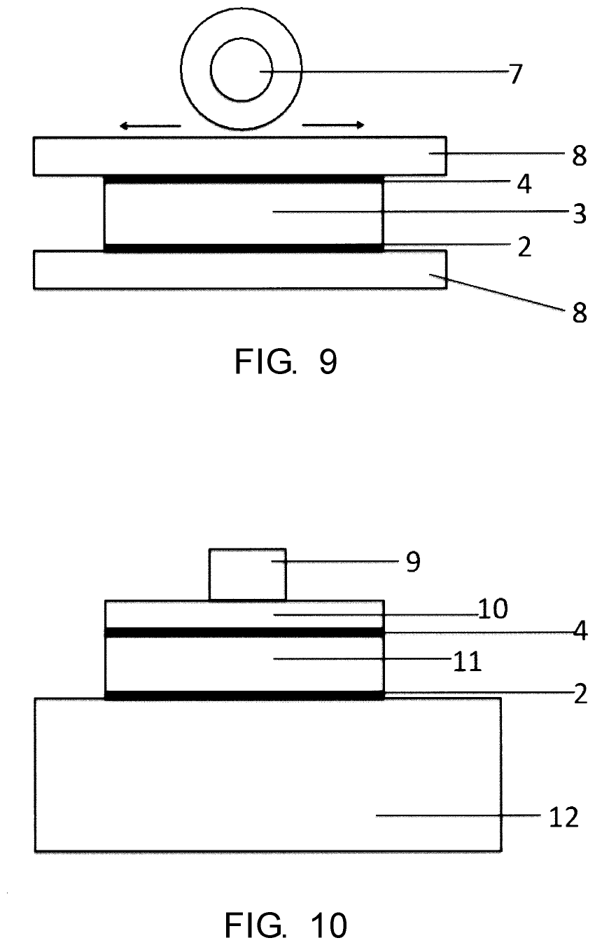

An overview of step 7 is illustrated in FIG. 9. In step 7, one more aluminum plate is laminated on the open surface of the first adhesive layer, the sheet is heated while receiving a moderate pressing force from the outer surface of the newly laminated aluminum plate, and thereby the first adhesive layer adheres to the aluminum plates in the same manner as the above-described example of step 5. FIG. 9 illustrates the state in which the sheet is pressed by the roller (7). The arrows present on the lower side of the roller (7) indicate reciprocating motions of the roller (7). In this way, the graphite sheet is fixed between the two aluminum plates via the adhesive layer including the poly(vinyl formal) resin. Since the two aluminum plates, the adhesive layer, and the graphite sheet are one body having high thermal conductivity, it functions as a heat radiation member as a whole.

[Heat Radiation Member for Semiconductor Chip]

FIG. 10 illustrates a state in which an aluminum plate on which a semiconductor chip has been mounted is made to adhere to one surface of the graphite sheet in step 5 and the other surface of the graphite sheet is made to adhere to a large-size heat radiator in step 7. Using this method, the graphite sheet serving as a thermally conductive material layer can be firmly fixed between the aluminum plate on which a semiconductor chip has been mounted and the large-size heat radiator via the extremely thin first and second adhesive layers. As a result, a heat radiation member including a new graphite sheet is formed between the aluminum plate and the large-size heat radiator.

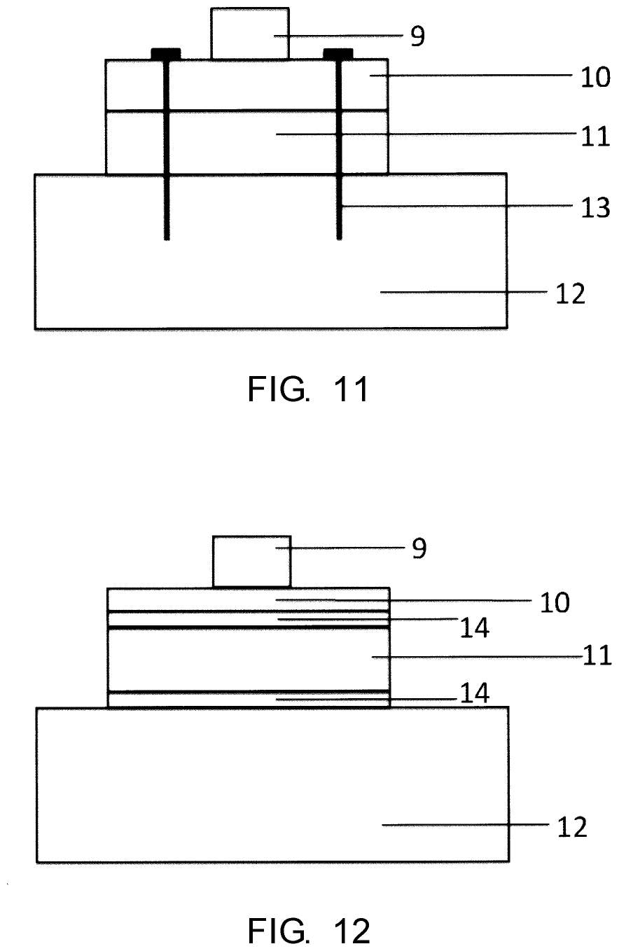

Meanwhile, in the conventional method illustrated in FIG. 11, holes are made in an aluminum plate on which a semiconductor chip has been mounted, a graphite sheet, and a large-size heat radiator, and the aluminum plate, the graphite sheet, and the large-size heat radiator are fixed together by causing bolts to penetrate the holes while applying strong pressure from the aluminum plate side. In this fixing method, it is necessary to use an aluminum plate having a thickness that can withstand the pressure.

In addition, in another conventional method illustrated in FIG. 12, thick double-sized tape made of an acryl resin is attached to both surfaces of the graphite sheet, and the outermost surfaces of the double-sized tape are made to adhere to each of the aluminum plate and the large-size heat radiator. In this method, since the double-sized tape part has low thermal conductivity, heat cannot be sufficiently radiated from the semiconductor chip which is a heat source.

In the example in which the transfer sheet of the present invention is used, a heat radiator having both excellent adhesiveness and thermal conductivity can be connected to the semiconductor chip that is a heat source with a smaller number of components than in the conventional technologies. As in Example 1, if the transfer sheet of the present invention is used, a heat radiation member having both excellent adhesiveness and thermal conductivity can be formed with a smaller number of components in a smaller space.

### EXAMPLES

[Materials Used]

The following materials are used in respective layers of the transfer sheet of the present invention and a comparative superimposition sheet.

(Release Layer and Carrier Film)
Releasable polyethylene terephthalate (PET) film product “Purex A55” manufactured by Teijin Film Solutions Limited (indicated as “A55” in Table 1) (adhesive layer).
Poly(vinyl formal) resin product “Vinylec K” manufactured by JNC Corporation, containing 81.1 weight % of the structural unit A, 11.0 weight % of the structural unit B, and 7.9 weight % the structural unit C with respect to a total amount of the structural units A, B, and C, weight-average molecular weight 45,000.
N-methyl pyrrolidone manufactured by Wako Pure Chemical Industry (solvent).
Adhesive tape NeoFix 5 (thickness: 5 μm) manufactured by Nichiei Kakou Co., Ltd. (for comparison).
Adhesive tape NeoFix 10 (thickness: 10 μm) manufactured by Nichiei Kakoh Co., Ltd. (for comparison).

Further the adhesive tapes for comparison are general members used in adhering a graphite sheet to various electronic devices.

(Thermally Conductive Material)
Graphite sheet product “SS 1500” manufactured by GrafTECH International Ltd. (thickness: 25 μm)
Graphite sheet product “HT 1205” manufactured by GrafTECH International Ltd. (thickness: 127 μm)
Graphite sheet product “SS 500” manufactured by GrafTECH International Ltd. (thickness: 76 μm) (protective layer)
Self-adhesive biaxially oriented polypropylene film product “FSA-010B” manufactured by Futamura Chemical Co., Ltd. (“FSA” of Table 1) (aluminum plate)
Corrosion-resistant aluminum plate A5052 (thickness: 0.4 mm)

### Example 1

A transfer sheet of the present invention was manufactured by performing the following steps 1, 2, 3, and 4 in this order.

(Step 1) A graphite sheet “SS 1500” was laminated on a carrier film “Purex A55.” A solution of a poly(vinyl formal) resin “Vinylec K” was applied onto the open surface of the graphite sheet using a Baker-type applicator and the surface to which this solution had been applied was dried in a thermostatic chamber of which the temperature was maintained to 90° C. In this way, a first adhesive layer having a thickness of 5 μm was formed on the graphite sheet.

(Step 2) A releasable PET film “Purex A55” was adhered to the first adhesive layer formed in step 1, and thereby a release layer was formed. Meanwhile, the carrier film was removed from the graphite sheet.

(Step 3) A solution of a poly(vinyl formal) resin “Vinylec K” was applied onto the open surface of the graphite sheet that has undergone step 2 using a Baker-type applicator, and the surface to which this solution had been applied was dried in a thermostatic chamber of which the temperature was maintained to 90° C. In this way, a second adhesive layer having a thickness of 5 μm was formed on the graphite sheet.

(Step 4) A protective layer including a protective film “FSA-010B” was formed by adhering it to the surface of the second adhesive layer formed in step 3. In this way, a transfer sheet 1 of the present invention in which the protective layer, the second adhesive layer, the graphite sheet, the first adhesive layer, and the release layer were laminated in this order was obtained.

A heat radiation member was manufactured by performing the following steps 5, 6, and 7 on the obtained transfer sheet 1 in this order.

(Step 5) The protective layer formed in step 4 was peeled off by hand, and the exposed second adhesive layer was made to adhere to an aluminum plate (A5052). All of the aluminum plate, second adhesive layer, graphite sheet, first adhesive layer, and release layer were heated at 175° C., and the aluminum plate and the graphite sheet were made to adhere to the second adhesive layer while being pressed by a roller weighing 2 kg from the outermost surface of the release layer.

(Step 6) The release layer was removed from the transfer sheet that had undergone step 5, and thereby the first adhesive layer was exposed.

(Step 7) The exposed first adhesive layer finished in step 6 was made to adhere to an aluminum plate (A5052). The entire aluminum plate, first adhesive layer, graphite sheet, second adhesive layer, and aluminum plate were heated at 175° C., and the aluminum plate was made to adhere to the graphite sheet via the first adhesive layer while being pressed by a roller weighing 2 kg from the outermost surface of the aluminum plate coming in contact with the first adhesive layer. In this way, a heat radiation member 1 in which the aluminum plate, the first adhesive layer, the graphite sheet, the second adhesive layer, and the aluminum plate were laminated in this order was obtained.

### Examples 2 to 9

By changing the materials used in Example 1 or changing the amount of the poly(vinyl formal) resin coated in steps 1 and 3 of Example 1, transfer sheets 2 to 9 of the present invention were manufactured as shown in Table 1. Heat radiation members 2 to 9 were manufactured by performing the same steps 5, 6, and 7 as in Example 1 on transfer sheets 2 to 9. Materials and layer structures of the obtained transfer sheets 1 to 9 and heat radiation members 1 to 9 are shown in Table 1.

TABLE 1

| | | Example 1 | Example 2 | Example 3 | Example 4 | Example 5 | Example 6 | Example 7 | Example 8 | Example 9 |
|---|---|---|---|---|---|---|---|---|---|---|
| Transfer sheet | No. | 1 | 2 | 3 | 4 | 5 | 6 | 7 | 8 | 9 |
| | Release layer | A55 | A55 | A55 | A55 | A55 | A55 | A55 | A55 | A55 |
| | First adhesive layer | Vinylec K | Vinylec K | Vinylec K | Vinylec K | Vinylec K | Vinylec K | Vinylec K | Vinylec K | Vinylec K |
| | Thickness (μm) | 5 | 1 | 10 | 1 | 5 | 10 | 1 | 5 | 10 |
| | Thermally | SS 1500 | SS 1500 | SS 1500 | HT 1205 | HT 1205 | HT 1205 | SS 500 | SS 500 | SS 500 |
| | conductive material | | | | | | | | | |
| | layer | | | | | | | | | |
| | Second adhesive | Vinylec K | Vinylec K | Vinylec K | Vinylec K | Vinylec K | Vinylec K | Vinylec K | Vinylec K | Vinylec K |
| | layer | 5 | 1 | 10 | 1 | 5 | 10 | 1 | 5 | 10 |
| | Thickness (μm) | | | | | | | | | |
| | Protective layer | FAS | FAS | FAS | FAS | FAS | FAS | FAS | FAS | FAS |
| Heat radiation | No. | 1 | 2 | 3 | 4 | 5 | 6 | 7 | 8 | 9 |
| member | Aluminum plate | A5052 | A5052 | A5052 | A5052 | A5052 | A5052 | A5052 | A5052 | A5052 |
| | First adhesive layer | Vinylec K | Vinylec K | Vinylec K | Vinylec K | Vinylec K | Vinylec K | Vinylec K | Vinylec K | Vinylec K |
| | Thickness | 5 | 1 | 10 | 1 | 5 | 10 | 1 | 5 | 10 |
| | (μm) | | | | | | | | | |
| | Thermally | SS 1500 | SS 1500 | SS 1500 | HT 1205 | HT 1205 | HT 1205 | SS 500 | SS 500 | SS 500 |
| | conductive material | | | | | | | | | |
| | layer | | | | | | | | | |
| | Second adhesive | Vinylec K | Vinylec K | Vinylec K | Vinylec K | Vinylec K | Vinylec K | Vinylec K | Vinylec K | Vinylec K |
| | layer | 5 | 1 | 10 | 1 | 5 | 10 | 1 | 5 | 10 |
| | Thickness (μm) | | | | | | | | | |
| | Aluminum plate | A5052 | A5052 | A5052 | A5052 | A5052 | A5052 | A5052 | A5052 | A5052 |
| Evaluation of | Adhesiveness of | + | + | + | + | + | + | + | + | + |
| heat radiation | aluminum plate to | | | | | | | | | |
| member | graphite sheet | | | | | | | | | |
| | Thermal resistance | 0.98 | 0.87 | 1.62 | 0.66 | 1.08 | 0.62 | 0.85 | 0.90 | 1.33 |
| | (Kcm²/W) | | | | | | | | | |

Further, in all of the transfer sheets 1 to 9 and the heat radiation members 1 to 9, the release property of the protective layer was good when the protective layer of the transfer sheet was peeled off in step 5. That is, since adhesiveness of the protective layer to the second adhesive layer was weak, the protective layer could be separated from the second adhesive layer without resistance.

In addition, in any of the transfer sheets 1 to 9 and the heat radiation members 1 to 9, the release property of the release layer was good when the release layer of the transfer sheet was peeled off in step 6. That is, since adhesiveness of the release layer to the first adhesive layer was weak, the release layer could be separated from the first adhesive layer without resistance.

As described above, a large force is unnecessary for the operation of transferring the thermally conductive material layer from the transfer sheet of the present invention to the aluminum plate. The heat radiation member can be fixed to a heating element with a simple operation using the transfer sheet of the present invention.

Next, the following comparative products were manufactured.

### Comparative Examples 1, 4, and 7

Comparative heat radiation members 1, 4, and 7 were manufactured without using an adhesive layer. That is, an aluminum plate, a graphite sheet, and an aluminum plate were laminated in this order as shown in Table 2.

### Comparative Examples 2, 3, 5, 6, 8, and 9

Comparative heat radiation members 2, 3, 5, 6, 8, and 9 were manufactured using an adhesive tape for adhesive layers. That is, an aluminum plate, an adhesive tape, a graphite sheet, an adhesive tape, and an aluminum plate were laminated in this order using the materials shown in Table 2.

TABLE 2

| | | Compar- | Compar- | Compar- | Compar- | | | | | |
|---|---|---|---|---|---|---|---|---|---|---|
| | | ative | ative | ative | ative | Comparative | Comparative | Comparative | Comparative | Comparative |
| | | example 1 | example 2 | example 3 | example 4 | example 5 | example 6 | example 7 | example 8 | example 9 |
| Heat | No. | 1 | 2 | 3 | 4 | 5 | 6 | 7 | 8 | 9 |
| radiation | Aluminum | A5052 | A5052 | A5052 | A5052 | A5052 | A5052 | A5052 | A5052 | A5052 |
| member | plate | | | | | | | | | |
| | First | | NeoFix5 | NeoFix 10 | | NeoFix5 | NeoFix 10 | | NeoFix5 | NeoFix 10 |
| | adhesive | | 5 | 10 | | 5 | 10 | | 5 | 10 |
| | layer | | | | | | | | | |
| | Thickness | | | | | | | | | |
| | (μm) | | | | | | | | | |
| | Thermally | SS 1500 | SS 1500 | SS 1500 | HT 1205 | HT 1205 | HT 1205 | SS 500 | SS 500 | SS 500 |
| | conductive | | | | | | | | | |
| | material | | | | | | | | | |
| | layer | | | | | | | | | |
| | Second | | NeoFix5 | NeoFix 10 | | NeoFix5 | NeoFix 10 | | NeoFix5 | NeoFix 10 |
| | adhesive | | 5 | 10 | | 5 | 10 | | 5 | 10 |
| | layer | | | | | | | | | |
| | Thickness | | | | | | | | | |
| | (μm) | | | | | | | | | |
| | Aluminum | A5052 | A5052 | A5052 | A5052 | A5052 | A5052 | A5052 | A5052 | A5052 |
| | plate | | | | | | | | | |
| Evaluation | Adhesiveness | − | + | + | − | + | + | − | + | + |
| of heat | of aluminum | | | | | | | | | |
| radiation | plate to | | | | | | | | | |
| member | graphite | | | | | | | | | |
| | sheet | | | | | | | | | |
| | Thermal | 0.58 | 1.08 | 2.05 | 0.57 | 1.21 | 2.21 | 0.86 | 1.08 | 1.60 |
| | resistance | | | | | | | | | |
| | (Kcm²/W) | | | | | | | | | |

The heat radiation members 1 to 9 of the present invention and the comparative heat radiation members 1 to 9 were evaluated according to the following points. The results are shown in Tables 1 and 2.

(Adhesiveness of Aluminum Plate to Graphite Sheet)

The aluminum plates were peeled off from the obtained heat radiation members by hand, and the surface states of the exposed aluminum plates were visually observed. The adhesiveness of the aluminum plates to the graphite sheets was determined according to the following criteria based on the observed surface states.

+: Good. The entire exposed surfaces were covered with graphite. The inside of the entire graphite sheet was seen to have been peeled off to the level of the aluminum plate.

−: Poor. No graphite was observed in most of or all of exposed surfaces. The graphite layers were seen not to have follow the aluminum plates when they were released.

(Thermal Resistance)

Thermal resistance ((Kcm2/W) of the obtained heat radiation members were measured using a thermal resistance measuring instrument TCM 100 manufactured by RHESCA Co., Ltd. For the measurement, a thin layer of silicone grease was coated on the aluminum surfaces of the heat radiation members, a cartridge was caused to slide on the coated surfaces so that grease was applied, and the cartridge was made to adhere to the coated surfaces while minimizing occurrence of voids on the contact surfaces. A thin layer of grease was coated on the lower surfaces of the heated blocks and upper surfaces of the cooled blocks, and they were placed in a device. Measurement was performed at a heated block temperature of 100° C., a cooled block temperature of 20° C., and at a weight of 100 N.

The heat radiation members 1, 5, and 8 obtained from the transfer sheets 1, 5, and 8 of the present invention were members in which both surfaces of the graphite sheets were made to adhere to the aluminum plates via the adhesive layers each having a thickness of 5 μm. On the other hand, the comparative heat radiation members 2, 5, and 8 were members in which both surfaces of the graphite sheets were made to adhere to the aluminum plates via adhesive tapes each having a thickness of 5 μm. Although the thicknesses of the layers between the graphite sheets and the aluminum plates were the same in the heat radiation members 1, 5, and 8 and the comparative heat radiation members 2, 5, and 8, the heat radiation members 1, 5, and 8 exhibited lower thermal resistance and a better heat radiation function than the comparative heat radiation members 2, 5, and 8.

The heat radiation members 3, 6, and 9 obtained from the transfer sheets 3, 6, and 9 of the present invention were members in which both surfaces of the graphite sheets were made to adhere to the aluminum plates via adhesive layers each having a thickness of 10 μm. On the other hand, the comparative heat radiation members 3, 6, and 9 were members in which both surfaces of the graphite sheets were made to adhere to the aluminum plates via the adhesive tapes each having a thickness of 10 μm. Although the thicknesses of the layers between the graphite sheets and the aluminum plates were the same in the heat radiation members 3, 6, and 9 and the comparative heat radiation members 3, 6, and 9, the heat radiation members 3, 6, and 9 exhibited lower thermal resistance and a better heat radiation function than the comparative heat radiation members 3, 6, and 9.

The heat radiation members 2, 4, and 7 obtained from the transfer sheets of the present invention were members in which both surfaces of the graphite sheets were made to adhere to the aluminum plates via the adhesive layers each having a thickness of 1 μm. Even though the adhesive layers of the heat radiation members 2, 4, and 7 were extremely thin, the aluminum plates firmly adhered to the graphite sheets. Since extremely thin adhesive layers were interposed in the heat radiation members 2, 4, and 7, low thermal resistance comparable to the comparative heat radiation members 1, 4, and 7 in which the aluminum plates were in direct contact with the graphite sheets was attained.

As described above, when the transfer sheet of the present invention is used, a thin and miniaturized heat radiation member having an excellent heat radiation function in comparison to the related art can be firmly fixed to a heating element.

By using the transfer sheet of the present invention, a more miniaturized and highly functional heat radiation member can be attached to electronic devices and heating elements having electronic components through a simple operation. The transfer sheet of the present invention and the production method for a heat radiation member using the sheet contribute to manufacturing of more miniaturized and accurate electronic devices.

### REFERENCE SIGNS LIST

1 Release layer
2 First adhesive layer
3 Thermally conductive material layer
4 Second adhesive layer
5 Protective layer
6 Carrier film
7 Roller
8 Aluminum plate
9 Semiconductor chip
10 Aluminum plate
11 Graphite sheet
12 Large-size heat radiator
13 Bolt
14 Double-sided tape

1. A transfer sheet, comprising a release layer comprising a releasable film, a first adhesive layer comprising a poly(vinyl formal) resin, a thermally conductive material layer comprising a carbon material, and a second adhesive layer comprising a poly(vinyl formal) resin being laminated in sequence.

2. The transfer sheet according to claim 1, wherein the poly(vinyl formal) resin comprises following structural units A, B, and C,

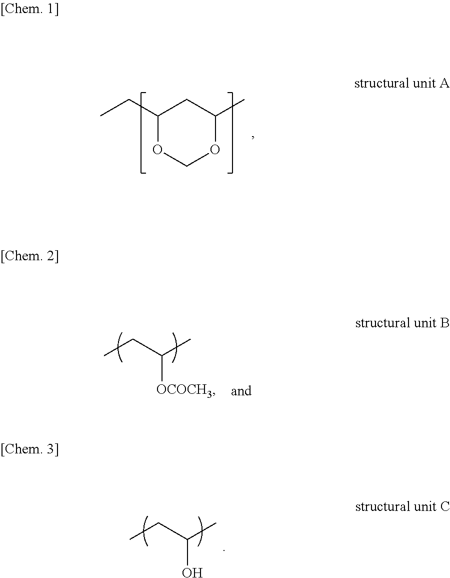

3. The transfer sheet according to claim 2, wherein the structural units A, B, and C in the poly(vinyl formal) resin are bonded at random, a content of the structural unit A is 80 to 82 weight %, a content of the structural unit B is 9 to 13 weight %, and a content of the structural unit C is 5 to 7 weight % with respect to the total amount of the structural units A, B, and C.

4. The transfer sheet according to claim 3, wherein a weight-average molecular weight of the poly(vinyl formal) resin is in a range of 30,000 to 150,000.

5. The transfer sheet according to claim 1, wherein the thermally conductive material layer is made of a carbon material selected from graphite, graphene, and carbon nanotubes.

6. The transfer sheet according to claim 1, wherein a thickness of each of the first and second adhesive layers is in a range of 1 to 20 μm.

7. A manufacturing method for the transfer sheet according to claim 1, comprising preforming following steps 1, 2, and 3 in sequence:
(step 1) a step of forming the first adhesive layer comprising a poly(vinyl formal) resin on an open surface of the thermally conductive material layer made of the carbon material formed on a carrier film;
(step 2) a step of forming the release layer comprising the releasable film on an open surface of the first adhesive layer and removing the carrier film from the thermally conductive material layer; and
(step 3) a step of forming the second adhesive layer comprising a poly(vinyl formal) resin on the open surface of the thermally conductive material layer.

8. The manufacturing method for the transfer sheet according to claim 7, further comprising performing following step 4 after the step 3:
(step 4) a step of forming a protective layer on an open surface of the second adhesive layer.

9. A formation method for a heat radiation member using the transfer sheet according to claim 1, comprising preforming following steps 5, 6, and 7 in sequence:
(step 5) a step of thermally compression-bonding an outermost surface of the second adhesive layer forming the transfer sheet to an item;
(step 6) a step of removing the release layer forming the transfer sheet; and
(step 7) a step of thermally compression-bonding an outermost surface of the first adhesive layer forming the transfer sheet to the item.

10. The formation method for the heat radiation member according to claim 9, wherein at least one of the items has an electronic component as a heat source.

11. The transfer sheet according to claim 2, wherein the thermally conductive material layer is made of a carbon material selected from graphite, graphene, and carbon nanotubes.

12. The transfer sheet according to claim 3, wherein the thermally conductive material layer is made of a carbon material selected from graphite, graphene, and carbon nanotubes.

13. The transfer sheet according to claim 4, wherein the thermally conductive material layer is made of a carbon material selected from graphite, graphene, and carbon nanotubes.

14. The transfer sheet according to claim 2, wherein a thickness of each of the first and second adhesive layers is in a range of 1 to 20 μm.

15. The transfer sheet according to claim 3, wherein a thickness of each of the first and second adhesive layers is in a range of 1 to 20 μm.

16. The transfer sheet according to claim 4, wherein a thickness of each of the first and second adhesive layers is in a range of 1 to 20 μm.

17. The transfer sheet according to claim 5, wherein a thickness of each of the first and second adhesive layers is in a range of 1 to 20 μm.

18. The transfer sheet according to claim 11, wherein a thickness of each of the first and second adhesive layers is in a range of 1 to 20 μm.

19. The transfer sheet according to claim 12, wherein a thickness of each of the first and second adhesive layers is in a range of 1 to 20 μm.

20. The transfer sheet according to claim 13, wherein a thickness of each of the first and second adhesive layers is in a range of 1 to 20 μm.
